(19) United States
(12) Patent Application Publication
(10) Pub. No.: US 2026/0022953 A1
(43) Pub. Date: Jan. 22, 2026

(54) APPARATUS INCLUDING A CHAMBER AND A SENSOR AND A METHOD OF USING THE APPARATUS

(71) Applicant: CANON KABUSHIKI KAISHA, Tokyo (JP)

(72) Inventors: Steven C. SHACKLETON, Austin, TX (US); Byung-Jin Choi, Austin, TX (US); Seth J. Bamesberger, Austin, TX (US); David Matthew Galvin, Austin, TX (US); Shinichi SHUDO, Saitama (JP); Takahiro YOSHIDA, Utsunomiya (JP)

(21) Appl. No.: 18/780,371

(22) Filed: Jul. 22, 2024

(51) Int. Cl. G01D 5/48; H01L 21/67

(52) U.S. Cl. CPC G01D 5/48; H01L 21/67259

(57) ABSTRACT

An apparatus can include a chamber, a sensor, and a controller. The chamber can include a processing zone, wherein the chamber is adapted to support a workpiece along a substrate support plane. The sensor can be adapted to receive a radiation beam adapted to pass through the processing zone and generate a signal in response to receiving the radiation beam. The radiation beam can propagate along a line that is at an acute angle relative to the substrate support plane, and the sensor is outside the processing zone. The controller can be adapted to receive the signal and determine information regarding a position of the workpiece in response to receiving the signal. A method of manufacturing an electronic device can use the apparatus to ensure a workpiece is properly positioned while the workpiece is within a processing chamber.

### FIELD OF THE DISCLOSURE

The present disclosure relates to an apparatus including a chamber and a sensor and a method of using the apparatus.

### RELATED ART

A workpiece can be processed within a processing chamber. When the workpiece is properly positioned within the chamber, the workpiece is not damaged or misprocessed in the chamber. During processing, the processing chamber can have an environment that is too harsh for a positioning sensor to be used in positioning the workpiece. The processing environment may not allow a positioning sensor to be located within the processing chamber. Some processing tools position the workpiece before it enters the processing chamber and assume that a substrate positioning tool introduces no error between the time the position of the workpiece is determined outside the processing chamber and another time after the workpiece is placed within the processing chamber. If there is any error, the likelihood of damaging or misprocessing the workpiece significantly increases. A need exists to determine accurately the position of a workpiece when the workpiece is within a processing chamber.

### SUMMARY

In an aspect, an apparatus can include a chamber, a first sensor, and a controller. The chamber can include a processing zone, wherein the chamber is adapted to support a workpiece along a substrate support plane. The first sensor can be adapted to receive a first radiation beam adapted to pass through the processing zone and generate a first signal in response to receiving the first radiation beam. The first radiation beam can propagate along a first line that is at a first acute angle relative to the substrate support plane, and the first sensor is outside the processing zone. The controller can be adapted to receive the first signal and determine first information regarding a position of the workpiece within the chamber in response to receiving the first signal.

In an implementation, the first acute angle is in a range from 0° to 9.9°.

In another implementation, the workpiece includes a substrate and a cured planarization layer.

In still another implementation, the chamber further includes a plurality of substrate support pins having distal ends, wherein the distal ends of at least three substrate support pins within the plurality of substrate support pins lie along the substrate support plane.

In yet another implementation, the chamber further includes a lid adapted to be moved to a closed position after all of the workpiece is determined to be within the processing zone, and, from a top view, the lid does not overlap or underlap the first sensor.

In a further implementation, the apparatus further includes a second sensor. The second sensor is adapted to receive a second radiation beam adapted to pass through the processing zone and generate a second signal in response to receiving the second radiation beam. The second radiation beam propagates along a second line that is at a second acute angle relative to the substrate support plane, and the second sensor is outside the processing zone. The controller is adapted to receive the second signal and determine second information regarding the position of the workpiece in response to receiving the second signal.

In a particular implementation, the chamber further includes a plurality of substrate support pins adapted to move the workpiece in at least an X-direction or a Y-direction that is parallel to the substrate support plane.

In another particular implementation,

$$0. ° \leq \vert ( α - β ) \vert \leq 0.1 ° , \qquad Equation 1$$

where α is the first acute angle, and β is the second acute angle.

In still another particular implementation,

$$0.1 ° < \vert ( α - β ) \vert \leq 9.9 ° , \qquad Equation 2$$

where α is the first acute angle, and β is the second acute angle.

In a further particular implementation, the apparatus further includes a third sensor. The third sensor is adapted to receive a third radiation beam adapted to pass through the processing zone and along the substrate support plane and generate a third signal in response to receiving the third radiation beam. The third radiation beam propagates along a third line that is at a third acute angle relative to the support plane, and the third sensor is outside the processing zone. The controller is adapted to receive the third signal and determine third information regarding the position of the workpiece in response to receiving the third signal.

In a more particular implementation, the first radiation beam, the second radiation beam, and the third radiation beam do not interfere with one another.

In another implementation, the processing zone includes a high-temperature zone adapted to heat the workpiece.

In still another implementation, the processing zone includes a bake zone adapted to heat the workpiece overlying the workpiece in an ambient having at most 2 mol % O₂.

In a particular implementation, the apparatus includes a post-exposure bake unit adapted to bake a cured planarization layer and a cooling unit adapted to cool the workpiece, wherein the post-exposure bake unit is separate from the cooling unit.

In yet another implementation, the processing zone includes a deposition zone adapted to deposit a first material over the workpiece; includes an etch zone adapted to etch a second material within the workpiece; or is adapted to deposit a third material over the workpiece during a first point in time and etch a portion of the third material during a second point in time.

In a further implementation, the apparatus of further includes a component radiatively coupled to the first sensor, wherein the component includes a radiation reflector or a radiation emitter. The apparatus is adapted such that (1) the first sensor is at a first elevation above an elevation of the substrate support plane, and the component is at a second elevation below the elevation of the substrate support plane, or (2) the first sensor is at a third elevation below the elevation of the substrate support plane, and the component at a fourth elevation above the substrate support plane.

In another aspect, an apparatus can include a chamber including a processing zone, wherein the chamber is adapted to support a workpiece along a substrate support plane; a first substrate positioning tool adapted to move the workpiece along a chamber ingress path into the processing zone, wherein the chamber ingress path is along a first line; and a second substrate positioning tool adapted to move the workpiece along a chamber egress path out of the processing zone, wherein the chamber egress path is along a second line, and, from a top view, the second line intersects the first line. The apparatus can further include a first sensor adapted to receive a first radiation beam that passes through the processing zone and along the substrate support plane and generate a first signal in response to receiving the first radiation beam. The first sensor can be located outside the processing zone and where the first sensor does not contact the workpiece, the first substrate positioning tool, and the second substrate positioning tool at any time when the workpiece is moved along each of the chamber ingress path and the chamber egress path.

In an implementation, the chamber further includes a plurality of substrate support pins having distal ends, and the apparatus further includes a support pin actuator adapted to reversibly move the plurality of substrate support pins between a retracted state and an extended state. When in the extended state, the distal ends of at three support pins within the plurality of substrate support pins lie along the substrate support plane.

In another implementation, the apparatus further includes a cooling unit, and a third substrate positioning tool, wherein the processing zone is a high-temperature zone. The first substrate positioning tool is adapted to load the workpiece into the high-temperature zone along the chamber ingress path, the second substrate positioning tool is adapted to remove the workpiece from the high-temperature zone along the chamber egress path and load the workpiece into the cooling unit along a cooling unit ingress path, and the third substrate positioning tool is adapted to remove the workpiece from the cooling unit along a cooling unit egress path.

In a further aspect, a method of making an electronic device can include loading a workpiece onto support pins having distal ends, wherein the distal ends of at least three support pins lie along a substrate support plane, wherein the support pins are within a processing zone of a chamber; and receiving a first radiation beam at a first sensor, wherein the first radiation beam propagates along a line that is at a first acute angle relative to the substrate support plane, and the first sensor is outside the processing zone. The method can further include generating a first signal in response to receiving the first radiation beam, wherein generating is performed by the first sensor; receiving the first signal at a controller; and determining a first information regarding a position of the workpiece in response to receiving the first signal, wherein determining is performed by the controller.

In an implementation, during loading the workpiece onto the support pins, the workpiece includes a substrate and a cured planarization layer, wherein the substrate is disposed between the support pins and the cured planarization layer.

In another implementation, the method further includes baking the cured planarization layer within the processing zone to form a baked planarization layer, wherein baking the cured planarization layer is performed after determining the first information.

### BRIEF DESCRIPTION OF THE DRAWINGS

Implementations are illustrated by way of example and are not limited in the accompanying figures.

FIG. 1 includes conceptual views of a system that can be used in forming a baked planarization layer over a substrate.

FIG. 2 includes conceptual views of a post-exposure bake apparatus of the system of FIG. 1.

FIG. 3 includes an illustration of a cross-sectional view of a post-exposure bake section of the bake apparatus of FIG. 2.

FIG. 4A includes an illustration of a top view of a particular post-exposure bake station of the bake section in FIG. 3.

FIG. 4B includes an illustration of a cross-sectional view of a sensor housing including a sensor and a radiation emitter.

FIG. 5 includes an illustration of a cross-sectional view of a chamber of the post-exposure bake unit of FIG. 4A with substrate support pins in an extended state and further including a sensor housing-component pair and its corresponding radiation beam.

FIGS. 6 and 7 include illustrations of top and cross-sectional views of a workpiece, sensor housing-component pairs, and corresponding radiation beams in accordance with an implementation.

FIGS. 8 and 9 include illustrations of top and cross-sectional views of a workpiece, sensor housing-component pairs, and corresponding radiation beams in accordance with another implementation.

FIGS. 10 and 11 include illustrations of top and cross-sectional views of a workpiece, sensor housing-component pairs, and corresponding radiation beams in accordance with a further implementation.

FIG. 12 includes a conceptual view of an apparatus that can be used to deposit a layer or etch a workpiece.

FIG. 13 includes a cross-sectional view of a workpiece that includes a substrate and a cured planarization layer overlying the substrate.

FIGS. 14 and 15 include a process flow diagram for a method of forming a baked planarization layer from the cured planarization layer in FIG. 13.

FIG. 16 includes a cross-sectional view of a portion of a post-exposure bake unit that includes a substrate chuck, a plurality of substrate support pins in a retracted state, a chamber lid, and a processing zone.

FIG. 17 includes a cross-sectional view of the portion of the post-exposure bake unit of FIG. 16 after placing the plurality of substrate support pins in an extended state.

FIG. 18 includes a cross-sectional view of a portion of the post-exposure bake station of FIG. 4A after positioning the workpiece of FIG. 13 over the plurality of substrate support pins.

FIG. 19 includes a cross-sectional view of the portion of the post-exposure bake unit of FIG. 17 after positioning the workpiece of FIG. 13 over the plurality of substrate support pins.

FIG. 20 includes a cross-sectional view of the portion of the post-exposure bake unit of FIG. 19 after lowering the chamber lid to a closed position.

FIG. 21 includes a cross-sectional view of the portion of the post-exposure bake unit of FIG. 20 after placing the plurality of substrate support pins in a retracted state.

FIG. 22 includes a cross-sectional view of the portion of the post-exposure bake unit of FIG. 21, wherein the post-exposure bake unit includes a resistive heating element and a radiant heater.

FIG. 23 includes a cross-sectional view of the portion of the post-exposure bake unit of FIG. 22 after placing the plurality of substrate support pins in the extended state and raising the chamber lid.

FIG. 24 includes a top view of the portion of the post-exposure bake station of FIG. 18 after moving a substrate positioning tool under the workpiece.

FIG. 25 includes a top view of the portion of the post-exposure bake station of FIG. 24 after transferring the workpiece from the post-exposure bake unit to a cooling unit.

FIG. 26 includes a cross-sectional view of the workpiece overlying a portion of the cooling unit in FIG. 25, wherein the cooling unit includes a substrate chuck having a flow channel.

FIG. 27 includes a top view of the portion of the post-exposure bake station of FIG. 25 after removing the workpiece from the cooling unit.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

An apparatus can include a sensor that can be used to ensure that a workpiece is in a correct position while the workpiece is within a processing zone of a chamber. As used herein, the workpiece can be a substrate by itself when no layer is over or under the substrate or, when one more layers are over or under the substrate, the workpiece is a combination of the substrate and layer(s). During processing, the workpiece may be exposed to a harsh environment that may be at a high temperature (for example, at least 100° C.) or include a toxic, corrosive, flammable, pyrophoric, or other dangerous gas. The sensor may not be designed to withstand the harsh environment, and thus, the sensor can be positioned outside the processing zone.

The apparatus and corresponding method represent an improvement over a conventional apparatus. In a conventional apparatus that has a harsh processing environment, the position of the workpiece is determined when the workpiece is outside a processing chamber. A substrate positioning tool is used to position the workpiece within the processing chamber; however, the position of the workpiece is not directly determined when the workpiece is within the processing chamber. An assumption is made that the substrate positioning tool is operating properly and is properly calibrated. The assumption can be incorrect when the substrate positioning tool of the conventional apparatus is not operating properly, the workpiece shifts position on the positioning tool, or the substrate positioning tool drifts out of calibration. Thus, the likelihood of damaging or misprocessing the workpiece using the conventional apparatus is substantially greater than the apparatuses illustrated and described herein. The innovative apparatus and method eliminates the likelihood of issues described herein regarding the conventional apparatus.

In an implementation, the apparatus can include the chamber, the sensor, and a controller. The chamber can include the processing zone, wherein the chamber is adapted to support the workpiece along a substrate support plane. The sensor can be adapted to receive a radiation beam adapted to pass through the processing zone and generate a signal in response to receiving the radiation beam. The radiation beam can propagate along a line that is at an acute angle relative to the substrate support plane, and the sensor is outside the processing zone. The controller can be adapted to receive the signal and determine information regarding the position of the workpiece in response to receiving the signal. A method of manufacturing an electronic device can use the apparatus to ensure a workpiece is properly positioned while the workpiece is within a processing chamber. The apparatus and method are understood better after reading this specification in conjunction with the figures. Implementations described below are exemplary and do not limit the scope of the inventive concepts.

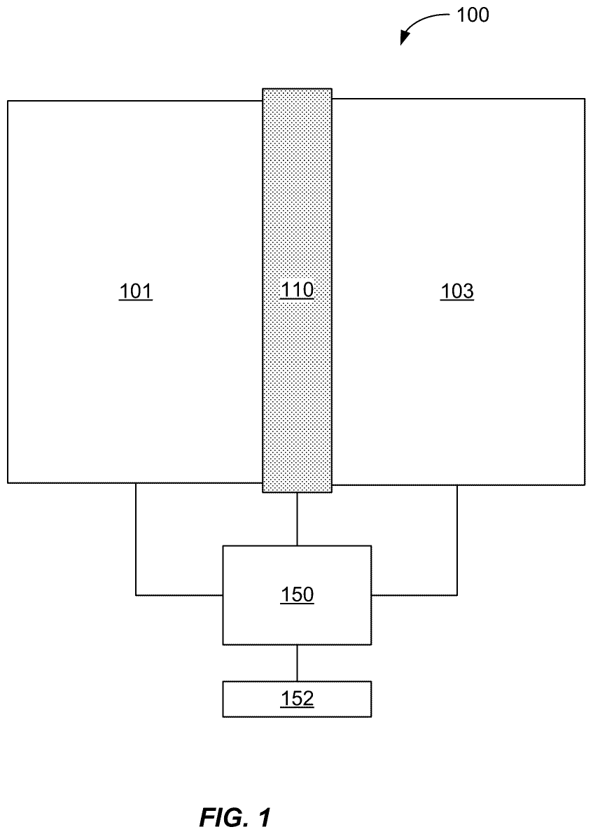

A system 100 illustrated in FIG. 1 can be used for the method. The apparatus is well suited for an Ink-jet Adaptive Planarization (IAP) process. The system 100 can be used to form a baked planarization layer from a polymerizable composition. The system 100 can include a cure apparatus 101, a post-exposure bake apparatus 103, a substrate transfer tool 110, a controller 150, and a memory 152. Referring to FIG. 1, the cure apparatus 101 includes components that can dispense a polymerizable composition, planarize the polymerizable composition to form a pre-cured planarization layer, and cure the pre-cured planarization layer to form a cured planarized layer. Techniques for curing the pre-cured planarization layer may include photocuring; lower temperature thermal curing; pressure curing; and chemical curing. The post-exposure bake apparatus 103 can be used to bake the cured planarization layer to form a baked planarization layer. The polymerizable composition will be mostly cured before baking. Some curing can occur during the post-exposure baking operation. Thus, as used herein a “cured planarization layer” may refer to a partly-cured and not fully-cured planarization layer. Lower temperature thermal curing is distinguished from baking in the present context in that a chamber lid with a tight tolerance between the workpiece and the chamber lid to control the baking atmosphere is not necessary, since there is little to no atmosphere concerns when lower temperature thermal curing is used.

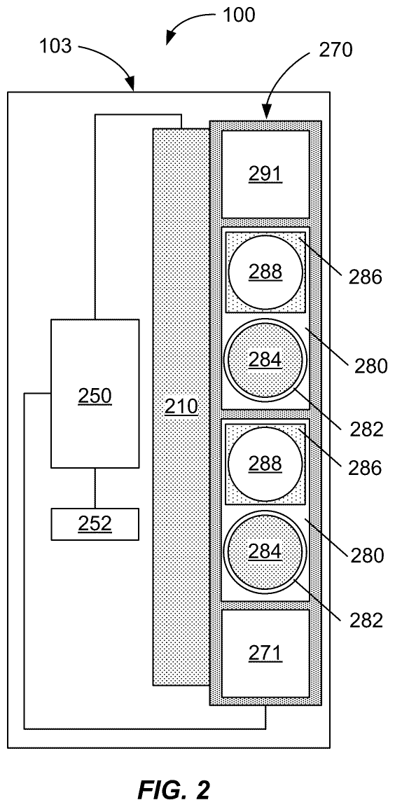

FIG. 2 includes a conceptual diagram of the post-exposure bake apparatus 103. The post-exposure bake apparatus 103 includes a post-exposure bake section 270, a substrate transfer tool 210, a controller 250, and a memory 252. The post-exposure bake section 270 can include the substrate pods 271 and 291 and post-exposure bake stations 280. The post-exposure bake stations 280 can further polymerize or crosslink the polymerizable composition within the cured planarization layer due to thermal curing, cause a different reaction of a component within the polymerizable composition, drive out a volatile component within the polymerizable composition, or the like. Each post-exposure bake station 280 can include a post-exposure bake unit 282 and a cooling unit 286, where the post-exposure bake unit 282 includes a substrate chuck 284, and the cooling unit 286 includes a substrate chuck 288.

Components within the system 100 are described in more detail below. Components that provide similar functionality, such as the substrate transfer tools 110 and 210, are addressed together in the description below.

The substrate transfer tool 110 can be adapted to transfer a workpiece between any of the cure apparatus 101, the post-exposure bake apparatus 103, and any one or more substrate pods. The substrate transfer tool 210 can be adapted to transfer at least one workpiece to or from any of the substrate pods 271 and 291, the post-exposure bake units 282 and the cooling units 286 of the post-exposure bake stations 280 and any one or more other substrate pods. Either or both of the substrate transfer tools 110 and 210 can include one or more substrate positioning tools that are adapted to precisely place workpieces.

The substrate transfer tools 110 and 210 may be or include at least one component of an Equipment Front End Module (EFEM). The components of the EFEM can include at least one of each of the following: a robot arm, a robot hand adapted for holding workpieces, a sensor, a motor for moving the robot arm, another motor for moving the robot arm, and the like. The robot arm can be adapted to move the workpiece with or without a layer between stations, for example, to or from any of the substrate pods 271 and 291, any of the post-exposure bake units 282, any of the cooling units 286, or a combination thereof. The substrate transfer tool 210 in FIG. 2 can be identical to or different from the substrate transfer tool 110 in FIG. 1.

The controller 150 is coupled to the cure apparatus 101, the post-exposure bake apparatus 103, and substrate transfer tool 110, and the memory 152 and can control components within system 100 including the cure apparatus 101, the post-exposure bake apparatus 103, and the substrate transfer tool 110. The description of the controller 150 may apply to the controller 250 and the description of the memory 152 can apply to the memory 252 except as explicitly noted when addressing specific details of the system 100.

If needed or desired, any combination of the controllers, including the controllers 150 and 250, can communicate with each other. For example, one or both controllers 150 and 250 can be used to confirm that a particular lot of substrates with cured planarization layers at a substrate pod within the post-exposure bake section 270 have completed processing within the cure apparatus 101 before the substrates and cured planarization layers are baked at a post-exposure bake unit 282 in the post-exposure bake section 270.

The controller 150 and 250 can operate using a computer readable program, optionally stored in memory 152 or 252. Either or both of the controllers 150 and 250 can include a processor (for example, a central processing unit of a microprocessor or microcontroller), a field-programmable gate array (FPGA), an application specific integrated circuit (ASIC), or the like. Either or both of the controllers 150 and 250 can further include internal memory, such as a set of registers, a cache memory, a flash memory, or the like.

The controllers 150 and 250 can be within the system 100. In another implementation, at least one component, the post-exposure bake stations 280, the post-exposure bake units 282, the cooling units 286, or a combination thereof can include a local controller that provides some of the functionality that would otherwise be provided by the controller 150 or 250. More or fewer controllers and more or fewer memories may be used with respect to the system 100. In another implementation (not illustrated) of the system, one or both of the controllers 150 and 250 can be at least part of a computer external to the system 100, where such computer is bidirectionally coupled to the system 100.

Any or all of the memories 152 and 252 can include a non-transitory computer readable medium that includes instructions to carry out the actions associated with or between operations. Either or both of the memories 152 and 252 can include a set of registers, a cache memory, a flash memory, a hard drive, or the like. Either or both of the memories 152 and 252 can further include data tables that can be accessed by either or both of the controllers 150 and 250 to assist in determining an operating parameter, for example, parameters used in dispensing and curing a polymerizable composition to form a cured planarization layer, a position of a workpiece within a chamber, a post-exposure baking temperature, or another parameter used in the methods as described below.

More or fewer controllers and more or fewer memories may be used with respect to the system 100. In another implementation, a single controller can perform all of the functions described with respect to the controllers 150 and 250. Thus, one controller, rather than two controllers, may be used with the system 100. In a further implementation, the controller 150 may control the cure apparatus 101 and the post-exposure bake apparatus 103, and thus the controller 250 is not required, or the controller 250 may control the cure apparatus 101 and the post-exposure bake apparatus 103, and thus the controller 150 is not required. In another implementation, a single memory, rather than two or three memories, may be used with the system 100.

The substrate pods 271 and 291 can hold a plurality of workpieces. An example of a substrate pod is a Front Opening Unified Pod (FOUP) which is defined by industry standards (for example, SEMI E47.1-1106, 2012) as a pod for storing and transporting workpieces. The apparatuses described herein can include coupling plates, interface holes, and load ports for receiving and transferring substrates to and from one to four substrate pods. A workpiece can be removed from the substrate pod 271 or 291, processed at least one of the post-exposure bake stations 280, and returned to the substrate pod 271, 291, or another substrate pod when the bake operation is completed.

The post-exposure bake units 282 are adapted to bake cured planarization layers to form baked planarization layers. The post-exposure bake units 282 can have a heating means. The temperature used for post-exposure baking may be at least 300° C. The highest processing temperature associated with the post-exposure bake stations 280 may be as high as 500° C. The heating means can provide heat by thermal radiation, thermal conduction, or thermal convention. Non-limiting examples of a heating means can include a radiant heating element (for example, a heating lamp or the like), a resistive heating element, a fan or pump to inject or recirculate a heated gas (that maybe heated within or external to the chamber) within a chamber of a post-exposure bake unit 282.

The cooling units 286 are adapted to cool workpieces that include substrates and baked planarization layers, such that the workpieces can be transferred to substrate pods without causing damage to the substrate transfer tools, the substrate pods, or workpieces. The cooling units 286 can have cooling means. The cooling means can cool by thermal conduction or thermal convention. Non-limiting examples of a cooling means can include a pump that pumps a cooling fluid through a substrate chuck, a valve that allows a compressed gas to expand within the chamber, a fan or pump to inject or recirculate a cooling gas (that may or may not be cooled external to the chamber) within a cooling unit 286. An example of a cooling gas can be clean dry air, Ar, N₂, CO₂, or room temperature air within the ambient environment outside the post-exposure bake apparatus 103.

Each of the substrate chucks 284 and 288 can be a vacuum chuck, a pin-type chuck, a groove-type chuck, an electrostatic chuck, an electromagnetic chuck, or the like. The substrate chucks 284 and 288 may be the same type, for example, vacuum chucks, or may be of different types. The substrate chucks 284 and 288 may include a limited number of support features that are in direct contact with the workpieces. For example, one of the substrate chucks can be a vacuum chuck, and another one of the substrate chucks can be an electrostatic or electromagnetic chuck. Each of the substrate chucks 284 and 288 may or may not have a heating element, a cooling element, or both that can be used to heat or cool a workpiece, and if present, a superstrate overlying the workpiece. More details on designs of the substrate chucks are described later in this specification.

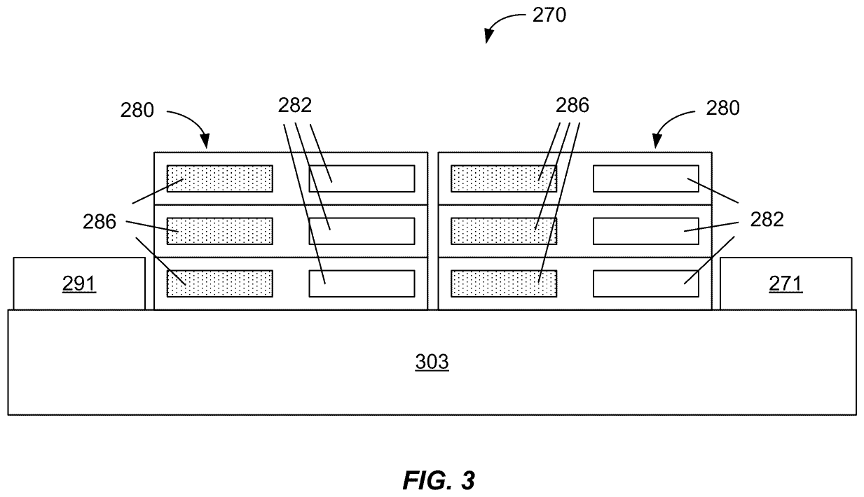

More details regarding the post-exposure bake section 270 are addressed before describing methods of using the post-exposure bake apparatus 103 that includes a base 303 upon which one or more post-exposure bake station 280 may be located. FIG. 3 illustrates a plurality of post-exposure bake stations 280 organized as a matrix of two columns and three rows. In another implementation, more or fewer post-exposure bake stations 280 and other organizations of the post-exposure bake stations 280 can be used. Stacking the post-exposure bake stations 280 can help to reduce the area occupied by the post-exposure bake stations 280. The number of post-exposure bake stations 280 within a stack can be two or more. Due to height constraints within a room where the post-exposure bake stations 280 are located and the height of each radiation exposure stations, the number of post-exposure bake stations 280 within a stack may be limited to 9 stations, 7 stations, or 5 stations. The number of stacks can be one or more. The number of stacks may be limited by available floor space within the room in which the cure section is located. The number of stacks of post-exposure bake stations 280 may be limited to 9 stacks, 7 stacks, or 5 stacks.

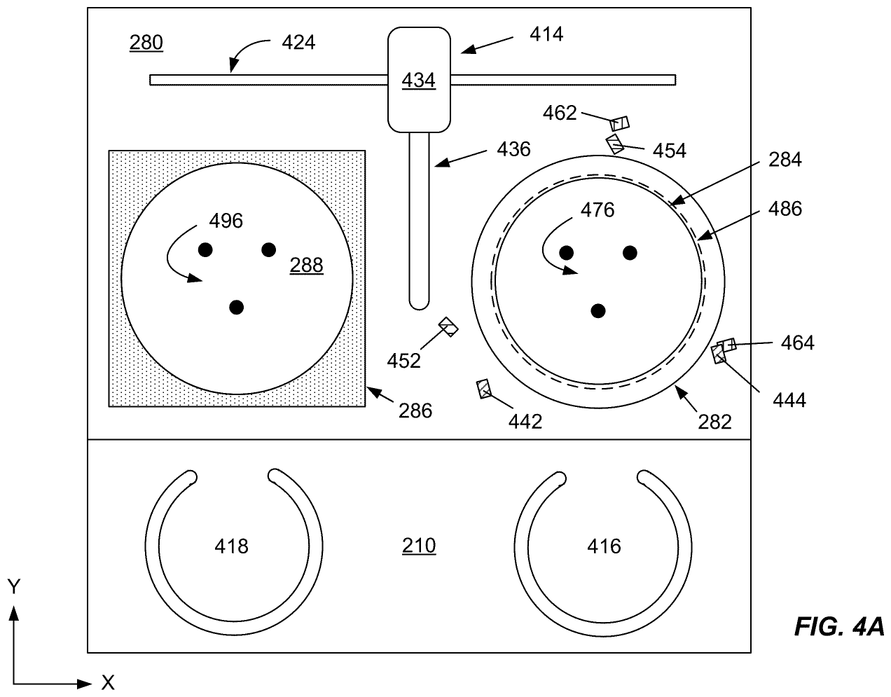

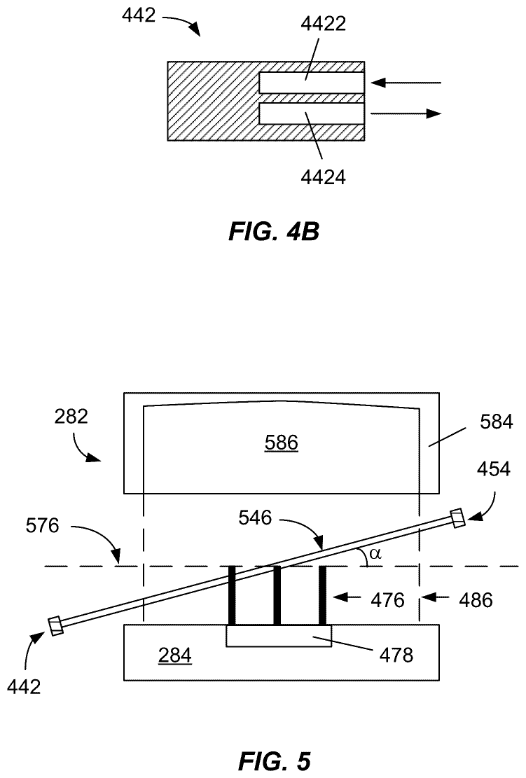

FIG. 4A includes as illustration of portions of the substrate transfer tool 210 and one of the post-exposure bake stations 280. The substrate transfer tool 210 includes a robot hand 416 of a substrate positioning tool that is adapted to move a workpiece along a chamber ingress path into the processing zone 486, which is illustrated with a dashed line. In an implementation, the processing zone 486 is a high-temperature zone, and more particularly, a bake zone. Although not illustrated, the substrate positioning tool may also include a robot arm coupled to the robot hand 416, a motor for moving the robot arm, another motor for moving the robot arm, and the like. In an alternative implementation, a different substrate positioning tool may be used. If the workpiece is positioned such that any of the workpiece extends outside the processing zone 486, the workpiece will be damaged when a lid (not illustrated in FIG. 4A) is lowered onto the base of the chamber.

The post-exposure bake unit 282 further includes a plurality of substrate support pins 476. The substrate support pins 476 can raise and lower a workpiece in the Z-direction (into and out of the drawing sheet). If needed or desired, the plurality of substrate support pins 476 may be adapted to move in the X-direction, Y-direction, or both directions. The X-direction and the Y-direction can be substantially parallel to the substrate support plane 576 described below with respect to FIG. 5, and the Z-direction can be substantially perpendicular to the substrate support plane 576. US Patent Application Publication No. 2012/0130529-A1 illustrates and describes an example of equipment that can move substrate support pins in the X-direction, Y-direction, and Z-direction. In another implementation, the plurality of substrate support pins do not move in the Z-direction, and a chucking surface of a substrate chuck may be raised and lowered. In such implementation, the plurality of substrate support pins may or may not be adapted to move in the X-direction, Y-direction, or both the X- and Y-directions. The plurality of substrate support pins 476 can be coupled to a support pin actuator 478 (illustrated in FIG. 5). The support pin actuator 478 can be adapted to extend or retract the plurality of substrate support pins 476 or a position between fully extended and fully retracted and may or may not be adapted to move the plurality of substrate support pins 476 in the X-direction and the Y-direction. The support pin actuator 478 may or may not be located within the substrate chuck 284. The support pin actuator 478 may be present and not illustrated in other drawings to simplify understanding of the post-exposure bake apparatus 103 and its operations.

The post-exposure bake station 280 further includes another substrate positioning tool 414 that can transfer a workpiece from the post-exposure bake unit 282 to the cooling unit 286. The substrate positioning tool 414 is adapted to move the workpiece along a chamber egress path out of the processing zone 486 and along a cooling unit ingress path to the substrate chuck 288 of the cooling unit 286. The substrate positioning tool 414 includes a body 434 that is coupled to a rail 424 and has an arm 436 that extends from the body 434. The arm 436 can be coupled to a workpiece over the substrate chuck 284, the substrate positioning tool 414 can lift and transfer the workpiece from the post-exposure bake unit 282 to the cooling unit 286, lower the workpiece onto the substrate chuck 288, and decouple the arm 436 from the workpiece. The substrate chuck 288 includes a plurality of substrate support pins 496 that may be substantially identical to or different from the plurality of substrate support pins 476. The plurality of substrate support pins 496 may have a corresponding support pin actuator that can provide any of the functionality as previously described with respect to the support pin actuator 478. The arm 436 may include an edge gripping end effector, or a bottom supporting edge effector which are used for holding the workpiece 622. The arm 436 can extend and withdraw the end effector (also called a hand) from between the substrate support pins 476 and 496. The transfer process can include: the substrate support pins 476 raise the workpiece 622; the end effector extends underneath the workpiece 622; the substrate support pins 476 are lowered; the arm moves along the rail 424 until the workpiece is over the substrate chuck 284 of the cooling unit 286; the substrate support pins 496 are raised until they support the workpiece 622; the end effector is removed from beneath the workpiece 622; and then the substrate support pins 496 are lowered until the workpiece 622 is resting on the substrate chuck 284.

The substrate transfer tool 210 includes a robot hand 418 of a substrate positioning tool that is adapted to remove the workpiece from the cooling unit along a cooling unit egress path. Although not illustrated, the substrate positioning tool may also include a robot arm coupled to the robot hand 418, a motor for moving the robot arm, another motor for moving the robot arm, and the like. In an alternative implementation, a different substrate positioning tool may be used. The substrate positioning tool that includes the robot hand 418 can be the same or different as compared to the substrate positioning tool that includes the robot hand 416.

During processing, the interior of a chamber of a processing unit, such as the post-exposure bake unit 282, can have a harsh processing environment that may include a temperature substantially above room temperature, that can be used to deposit a layer over a substrate or etch a material within a layer or a substrate. Most high quality radiation sensors, radiation emitters, or both may not be able to be used in such a harsh processing environment. The inventors have discovered a strategic placement of radiation sensors, radiation emitters, and if present, radiation reflectors that can allow the position of a workpiece to be determined while the workpiece is within the chamber, and more particularly, within the processing zone 486. The radiation sensors, radiation emitters, and if present, radiation reflectors can be placed so that they do not interfere with movement of workpieces or the proper operation of the chamber, the substrate positioning tools, and corresponding support equipment for any of the chamber and the substrate positioning tools.

The post-exposure bake station 280 further includes sensor housings 442, 452, and 462 and components 444, 454, and 464 that are adjacent to the post-exposure bake unit 282 and used in determining whether or not a workpiece is properly positioned so that the workpiece does not extend outside of the processing zone 486. Each of the sensor housing-component pairs can use a corresponding radiation beam, and the corresponding radiation beams do not interfere with each other.

Each of the sensor housings 442, 452, and 462 includes a sensor and may or may not include a radiation emitter. FIG. 4B includes a cross-sectional view of the sensor housing 442 that includes a sensor 4422 and a radiation emitter 4424 in accordance with an implementation. The arrows to the right of the sensor 4422 and the radiation emitter 4424 illustrate the direction radiation propagates with respect to the sensor 4422 and the radiation emitter 4424. The sensor 4422 can sense radiation emitted by the radiation emitter 4424. In another implementation, the sensor housing 442 can include the sensor 4422 and may not include the radiation emitter 4424. Each of the sensor housings 452 and 462 may have either of the implementation as described with respect to the sensor housing 442. The sensor 4422 can include at least one optical element (at least one aperture, lens, filter, etc.) that limit the impact of scattered light on the performance of the sensor 4422.

Components 444, 454, and 464 can include a radiation reflector or a radiation emitter. The sensor 4422 in the sensor housing 442 is radiatively coupled with the component 444, the sensor in the sensor housing 452 is radiatively coupled with the component 454, and the sensor in the sensor housing 462 is radiatively coupled with the component 464. FIG. 4A includes a sensor housing 442-component 444 pair, a sensor housing 452-component 454 pair, and a sensor housing 462-component 464 pair.

In an implementation, any one or all of the sensor housings 442, 452, and 462 can include a sensor and a radiation emitter, and its corresponding component 444, 454, or 464 can be a radiation reflector. Radiation can be emitted from the radiation emitter 4424 in the sensor housing 442, reflected by the radiation reflector of the component 444 back to the sensor 4422 in the sensor housing 442 where the radiation is sensed. The other sensor housing-component pairs can operate in substantially the same.

In another implementation, any one or all of the components 444, 454, and 464 can include a radiation emitter rather than a radiation reflector. Radiation can be emitted from the radiation emitter in the component 444 and be sensed by the sensor 4422 of the sensor housing 442. In this implementation, any or all the sensor housings 442, 452, and 462 may have a radiation emitter when the components 444, 454, and 464 are radiation emitters. Although present in the sensor housings 442, 452, and 462, the radiation emitters of the sensor housings 442, 452, and 462 may not be activated when determining the position of the workpiece.

In the description below, the sensor housing-component pairs will be described where each of the sensor housings include a sensor and its corresponding radiation emitter, and each of the components includes a radiation reflector. After reading this specification, skilled artisans will appreciate that the sensor housing-component pairs can be another design where the components are radiation emitters. Thus, radiation can be emitted from the radiation emitters of the components 444, 454, and 464 and received by sensors within the sensor housings 442, 452, and 462. Radiation reflectors are not required in this implementation.

FIG. 5 includes a cross-sectional view of at least a portion of the post-exposure bake unit 282. The post-exposure bake unit 282 further includes a chamber lid 584 that has a processing region 586, which in a particular implementation, includes at least a cavity within the chamber lid 584. The chamber lid 584 can be moved to a closed position and moved to a raised position without contacting the sensor housing 442 and the component 444 in FIG. 5, the sensor housing 452, the component 454 (not illustrated in FIG. 5), and the sensor housing 462, and the component 464 (not illustrated in FIG. 5). The chamber lid 584 may or may not overlap any one or more of the sensor housings 442, 452, 462, and the components 444, 454, and 464. The bottom surfaces of the chamber lid 584 do not overlap with any of the sensor housings 442, 452, 462, and the components 444, 454, and 464.

When the plurality of substrate support pins 476 are in an extended state, the distal ends of the plurality of substrate support pins 476 lie along a substrate support plane 576 as illustrated by the dashed line in FIG. 5. When the post-exposure bake unit 282 includes more substrate support pins, at least three of the substrate support pins lie along the substrate support plane 576. The sensor housing 442-component 444 pair is positioned such that the radiation beam 546 can propagate and intersect the substrate support plane 576 at an angle α. Depending on the geometries of a processing chamber and its corresponding components and support equipment, the angle α can be at most 45°, at most 30°, or at most 15°. In the same or different implementation, the angle α can be an acute angle and be at least 0.0° or at least 0.1°. In a particular implementation, the angle α can be in a range from 0.0° to 9.9°. The inventors have found that limiting the angle α to a narrow acute range of 0.1° to 9.9° can improve measurement sensitivity. When the radiation beam is larger than the workpiece 622, the workpiece 622 will block more of the radiation resulting in improved sensitivity. The applicant has also found that limiting the angle α to a narrow acute range of 0.1° to 9.9° can avoid interference with other sensors and moving components in the system.

For any one or more other sensor housing-component pairs, the angle of intersection between the corresponding radiation beam and the substrate support plane 576 can be any of the values previously described with respect to the angle α. In an implementation, the corresponding radiation beam for another sensor housing-component pair can propagate and intersect the substrate support plane 576 at an angle β. In an implementation, the angle β can be substantially the same as the angle. For example, the absolute value of the difference between the angles is at most 0.1°, or, when in the form of an equation,

$$0. ° \leq \vert ( α - β ) \vert \leq 0.1 ° . \qquad Equation 1$$

In another implementation, the angle α can be significantly different from the angle β. For example, the absolute value of the difference between the angles is greater than 0.1° and at most 9.9°, or, when in the form of an equation,

$$0.1 ° < \vert ( α - β ) \vert \leq 9.9 ° . \qquad Equation 2$$

In the implementation as illustrated in FIG. 5, the sensor housing 442, including its sensor and, if present, its radiation emitter, can be at an elevation below an elevation of the substrate support plane 576, and the component 444 is at an elevation above the elevation of the substrate support plane 576. Elevations are measured in a direction perpendicular to the substrate support plane 576 (between the top and bottom of the illustration in FIG. 5). In another implementation, the sensor housing 442, including its sensor and, if present, its radiation emitter, can be at an elevation above the elevation of the substrate support plane 576, and the component 444 is at an elevation below the elevation of the substrate support plane 576. For any one or more of the other sensor housing-component pairs, elevations of the sensor housing-component pair can have any of the relationships with respect to the substrate support plane 576 as previously described for the sensor housing 442-component 444 pair. As compared to the sensor housing 442-component 444 pair, the other sensor housing-component pairs may have the same or different elevational orientation as compared to the sensor housing 442-component 444 pair. For example, all sensor housings can be at elevations below the elevation of the substrate support plane 576, and all component pairs can be at elevations above the elevation of the substrate support plane 576. For a different example, one of the sensor housings may be at an elevation below the elevation of the substrate support plane 576, and another sensor housing may be at an elevation above the elevation of the substrate support plane 576.

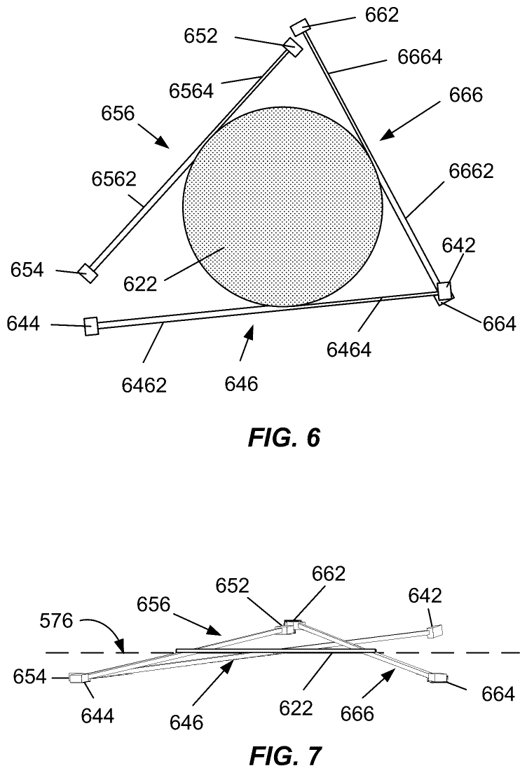

FIGS. 6 to 11 illustrate exemplary positional relationships between a workpiece 622, sensor housing-component pairs, and corresponding radiation beams. FIGS. 6 and 7 include top and side views, respectively, of a design that can be used to determine the position of the workpiece 622. FIG. 6 includes sensor housings 642, 652, and 662, components 644, 654, and 664, and radiation beams 646, 656, and 666. In the implementation as illustrated, the sensor housings 642, 652, and 662 include sensors and radiation emitters, and the components 644, 654, and 664 include radiation reflectors that reflect radiation emitted by the radiation emitters.

The radiation emitter of the sensor housing 642 emits the radiation beam 646 that is reflected by the radiation reflector at a radiation intensity as illustrated as the portion 6462 of the radiation beam 646. As the radiation beam 646 is reflected back to the sensor, the radiation beam 646 can be at least partly occluded by the workpiece 622. Depending on the position of the workpiece 622, the radiation beam 646 may or may not be completely occluded by the workpiece 622. The portion 6464 of the radiation beam 646 is narrower than the portion 6462 to illustrate the reduced radiation intensity due to the workpiece 622 partly occluding the radiation beam 646. In a further implementation, the component 644 is a radiation emitter that emits a radiation beam 646 in which the portion 6462 is at least partly occluded by the workpiece 622 to form portion 6464 which is received by the sensor 4422 of the sensor housing 642. The radiation is received by sensor within the sensor housing 642 will be at a radiation intensity corresponding to the portion 6464. Data can be collected that correlates the intensity of the radiation beam received by the sensor at the sensor housing 642 to a distance in a direction perpendicular to the radiation beam 646.

Similar relationships can be seen for the other sensor housing-component pairs and radiation beams. The radiation emitter of the sensor housing 652 emits the radiation beam 656 that is reflected by the radiation reflector at a radiation intensity as illustrated as the portion 6562 of the radiation beam 656. As the radiation beam 656 is reflected back to the sensor, the radiation beam 656 can be at least partly occluded by the workpiece 622. Depending on the position of the workpiece 622, the radiation beam 656 may or may not be completely occluded by the workpiece 622. The portion 6564 of the radiation beam 656 is narrower than the portion 6562 to illustrate the reduced radiation intensity due to the workpiece 622 partly occluding the radiation beam 656. In a further implementation, the component 654 is a radiation emitter that emits a radiation beam 656 in which the portion 6562 is at least partly occluded by the workpiece 622 to form portion 6564 which is received by the sensor 4422 of the sensor housing 652. The radiation is received by the sensor in the sensor housing 652 will be at a radiation intensity corresponding to the portion 6564. Data can be collected that correlates the intensity of the radiation beam received at the sensor of the sensor housing 652 to a distance in a direction perpendicular to the radiation beam 656.

The radiation emitter of the sensor housing 662 emits the radiation beam 666 that is reflected by the radiation reflector at a radiation intensity as illustrated as the portion 6662 of the radiation beam 666. As the radiation beam 666 is reflected back to the sensor, the radiation beam 666 can be at least partly occluded by the workpiece 622. Depending on the position of the workpiece 622, the radiation beam 666 may or may not be completely occluded by the workpiece 622. The portion 6664 of the radiation beam 666 is narrower than the portion 6662 to illustrate the reduced radiation intensity due to the workpiece 622 at least partly occluding the radiation beam 666. In a further implementation, the component 664 is a radiation emitter that emits a radiation beam 666 in which the portion 6262 is at least partly occluded by the workpiece 622 to form portion 6664 which is received by the sensor 4422 of the sensor housing 662. The radiation is received by the sensor of the sensor housing 662 will be at a radiation intensity corresponding to the portion 6664. Data can be collected that correlates the intensity of the radiation beam received at the sensor of the sensor housing 662 to a distance in a direction perpendicular to the radiation beam 666.

FIG. 7 includes a side view of the workpiece 622, the sensor housings 642, 652, and 662, the components 644, 654, and 664, and the radiation beams 646, 656, and 666. In the implementation illustrated in FIG. 7, the sensor housings 642, 652, and 662 are at elevations above the elevation of the substrate support plane 576, and the components 644, 654, and 664 are at elevations below the elevation of the substrate support plane 576.

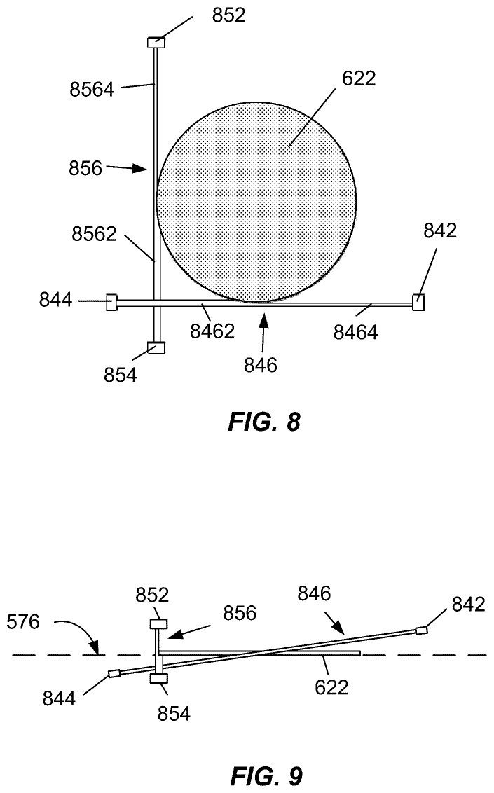

In another implementation, fewer or more sensor housing-component pairs can be used to determine the position of the workpiece when the workpiece is in the post-exposure bake unit 282. FIGS. 8 and 9 include top and side views, respectively, of a design that can be used to determine the position of the workpiece 622. FIG. 8 includes sensor housings 842 and 852, components 844 and 854, and radiation beams 846 and 856. In the implementation as illustrated, the sensor housings 842 and 852 include sensors and radiation emitters, and the components 844 and 854 include radiation reflectors that reflect radiation emitted by the radiation emitters.

The radiation emitter of the sensor housing 842 emits the radiation beam 846 that is reflected by the radiation reflector at a radiation intensity as illustrated as the portion 8462 of the radiation beam 846. As the radiation beam 846 is reflected back to the sensor, the radiation beam 846 can be at least partly occluded by the workpiece 622, depending on where the workpiece 622 is positioned. Depending on the position of the workpiece 622, the radiation beam 846 may or may not be completely occluded by the workpiece 622. The portion 8464 of the radiation beam 846 is narrower than the portion 8462 to illustrate the reduced radiation intensity due to the workpiece 622 partly occluding the radiation beam 846. In a further implementation, the component 844 is a radiation emitter that emits a radiation beam 846 in which the portion 8462 is at least partly occluded by the workpiece 622 to form portion 8464 which is received by the sensor 4422 of the sensor housing 842. The radiation is received by the sensor of the sensor housing 842 will be at a radiation intensity corresponding to the portion 8464. Data can be collected that correlates the intensity of the radiation beam received at the sensor of the sensor housing 842 to a distance in a direction perpendicular to the radiation beam 846.

The radiation emitter of the sensor housing 852 emits the radiation beam 856 that is reflected by the radiation reflector at a radiation intensity as illustrated as the portion 8562 of the radiation beam 856. As the radiation beam 856 is reflected back to the sensor, the radiation beam 856 can be at least partly occluded by the workpiece 622. Depending on the position of the workpiece 622, the radiation beam 656 may or may not be completely occluded by the workpiece 622. In a further implementation, the component 854 is a radiation emitter that emits a radiation beam 856 in which the portion 8562 is at least partly occluded by the workpiece 622 to form portion 8564 which is received by the sensor 4422 of the sensor housing 852. The portion 8564 of the radiation beam 856 is narrower than the portion 8562 to illustrate the reduced radiation intensity due to the workpiece 622 partly occluding the radiation beam 856. The radiation is received by the sensor of the sensor housing 852 will be at a radiation intensity corresponding to the portion 8564. Data can be collected that correlates the intensity of the radiation beam received at the sensor of the sensor housing 852 to a distance in a direction perpendicular to the radiation beam 856.

FIG. 9 includes a side view of the workpiece 622, the sensor housings 842 and 852, the components 844 and 854, and the radiation beams 846 and 856. In the implementation illustrated in FIG. 9, the sensor housings 842 and 852 are at elevations above the elevation of the substrate support plane 576, and the components 844 and 854 are at elevations below the elevation of the substrate support plane 576.

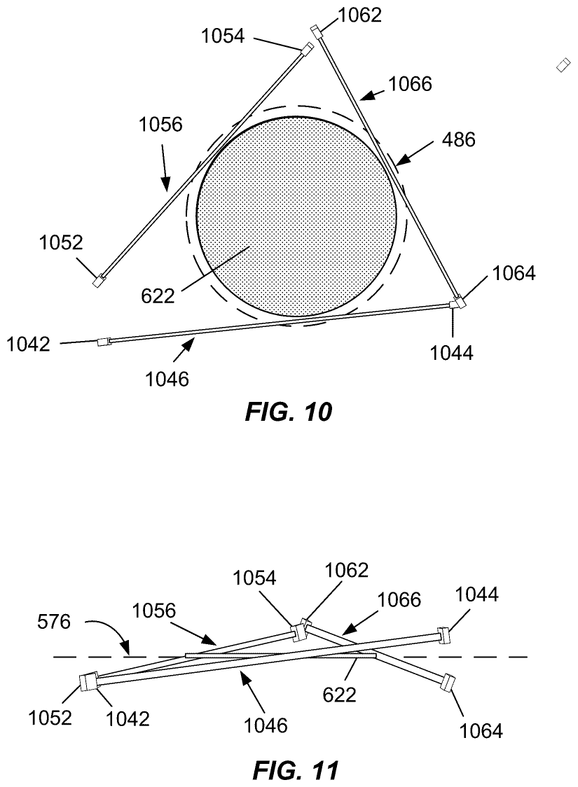

In a further implementation, one or more of the radiation beams may not be occluded, partly or completely, by a workpiece. The intensity of the radiation beams as sensed by the sensors can be substantially the same as the intensity of the radiation beams as emitted by the radiation emitters. FIGS. 10 and 11 include top and side views, respectively, of a design that can be used to determine the position of the workpiece 622. The positions of the sensor housing-component pairs is similar to but different from the positions of the sensor housing-component pairs in FIGS. 6 and 7.

FIG. 10 includes sensor housings 1042, 1052, and 1062, components 1044, 1054, and 1064, and radiation beams 1046, 1056, and 1066. In the implementation as illustrated, the sensor housings 1042, 1052, and 1062 include sensors and radiation emitters, and the components 1044, 1054, and 1064 include radiation reflectors that reflect radiation emitted by the radiation emitters.

The radiation emitter of the sensor housing 1042 emits a radiation beam 1046. At a location closest to the workpiece 622, the radiation beam 1046 passes between the workpiece 622 and the outer boundary of the processing zone 486 as illustrated by a dashed line and is reflected by the component 1044 that is received by the sensor of the sensor housing 1042. The radiation emitter of the sensor housing 1052 emits a radiation beam 1056. At a location closest to the workpiece 622, the radiation beam 1056 passes between the workpiece 622 and the outer boundary of the processing zone 486 and is reflected by the component 1054 that is received by the sensor of the sensor housing 1052. The radiation emitter of the sensor housing 1062 emits a radiation beam 1066. At a location closest to the workpiece 622, the radiation beam 1066 passes between the workpiece 622 and the outer boundary of the processing zone 486 and is reflected by the component 1064 that is received by the sensor of the sensor housing 1062. The controller 250 (FIG. 2) or a local controller can receive signals from the sensors of the sensor housings 1042, 1052, and 1062 and determine whether or not the sensed radiation has a sufficient intensity corresponding to the radiation beams 1046, 1056, and 1066 not being occluded by the workpiece 622.

The sensor can be triggered when the workpiece 622 is within a threshold distance (for example, 0.5 mm) of the outer boundary of the processing zone 486 which is defined by an inner wall of the chamber lid 584 that will be adjacent to the workpiece 622 once the chamber lid 584 is lowered. The threshold distance may be determined in part by one or more design criteria such as: size of the radiation beam; positioning accuracy of the robot hand 416; variation in the outer edge of processing zone 486, etc. The geometry of the radiation beams and the gap between the outer boundary of the processing zone 486 can be set such that in the worst-case movement direction, the radiation beam will be at least partly occluded before the workpiece offset has increased beyond a safe threshold.

FIG. 11 includes a side view of the workpiece 622, the sensor housings 1042, 1052, and 1062, the components 1044, 1054, and 1064, and the radiation beams 1046, 1056, and 1066. In the implementation illustrated in FIG. 11, the sensor housings 1042 and 1052 are at elevations below the elevation of the substrate support plane 576, and the sensor housing 1062 is at an elevation above the elevation of the substrate support plane 576. The components 1044 and 1054 are at elevations above the elevation of the substrate support plane 576, and the component 1064 is at an elevation below the elevation of the substrate support plane 576.

In another implementation, any of the components described with respect to FIGS. 6 to 11 can include radiation emitters, rather than radiation reflectors. The radiations beams are emitted from the radiation emitters, and at least some of the intensities of the radiation beams are received by the sensors without the use of the radiation reflectors as previously described.

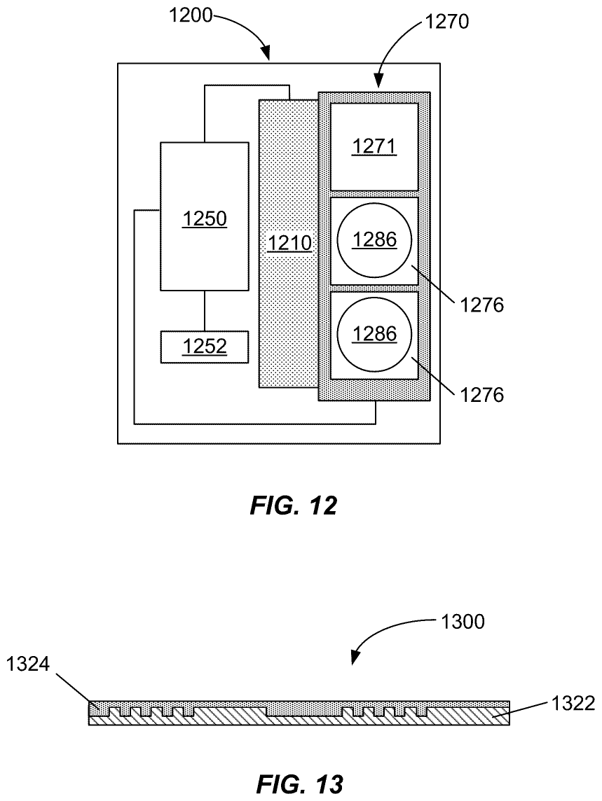

The concepts as described herein are not limited to equipment used to bake a cured planarization layer. Other processing tools may use the workpiece positioning designs and methods to ensure the workpiece is properly positioned within a chamber before processing the workpiece. FIG. 12 includes a conceptual diagram of a processing apparatus 1200. The processing apparatus 1200 can be a high-temperature processing apparatus, a deposition apparatus adapted to deposit a material onto a workpiece, an etch apparatus adapted to etch the workpiece, or the like. A high-temperature processing apparatus can be used activate a dopant implanted into the workpiece, perform a reaction between silicon and a metal to form a silicide, or the like. The deposition apparatus, the etch apparatus, or both may flow a toxic, corrosive, flammable, pyrophoric, or other dangerous gas. The deposition apparatus, the etch apparatus, or both may or may not operate at a temperature higher than 100° C. Any or all of the foregoing may perform processing in a harsh environment that may include a high temperature, a toxic, corrosive, flammable, pyrophoric, or other dangerous gas.

The processing apparatus 1200 includes a processing section 1270, a substrate transfer tool 1210, a controller 1250, and a memory 1252. The processing section 1270 can include a substrate pod 1271 and processing stations 1276 that can include substrate chucks 1286. The processing stations 1276 can be used for high-temperature processing, deposition, etching, or the like, and thus the processing stations 1276 can have a high-temperature zone, a deposition zone, an etch zone, or the like that is similar to the processing zone 486. The substrate transfer tool 1210, the controller 1250, and the memory 1252 can be any of those previously described with respect to the substrate transfer tool 210, the controller 250, and the memory 252, respectively.

Attention is directed to a method of forming a baked planarization layer using the system 100, including the cure apparatus 101 and the post-exposure bake apparatus 103 as described above. In the implementation described, the sensor housing-component pairs include sensor housings that include sensors and radiation emitters, and components include radiation reflectors that reflect radiation from the radiation emitters back to the sensors. The locations of the sensor housing-component pairs are illustrated and described with respect to FIGS. 6 and 7, and the workpiece partly, but not completely, occludes the radiation beams as radiation propagates from the radiation reflectors to the sensors. In other implementations, the sensor housing-component pairs can have as illustrated and described with respect to FIGS. 8 to 11. In any of the same or different implementations, the sensor housing-component pairs can include sensor housings each of which may or may not include a radiation emitter, and the components can be radiation emitters.

In an implementation as illustrated in FIG. 13, a workpiece 1300 can include a substrate 1322 and a cured planarization layer 1324. The workpiece 1300 at this point in the method may have been processed within the cure apparatus 101, and the cured planarization layer 1324 can be formed from a polymerizable composition.

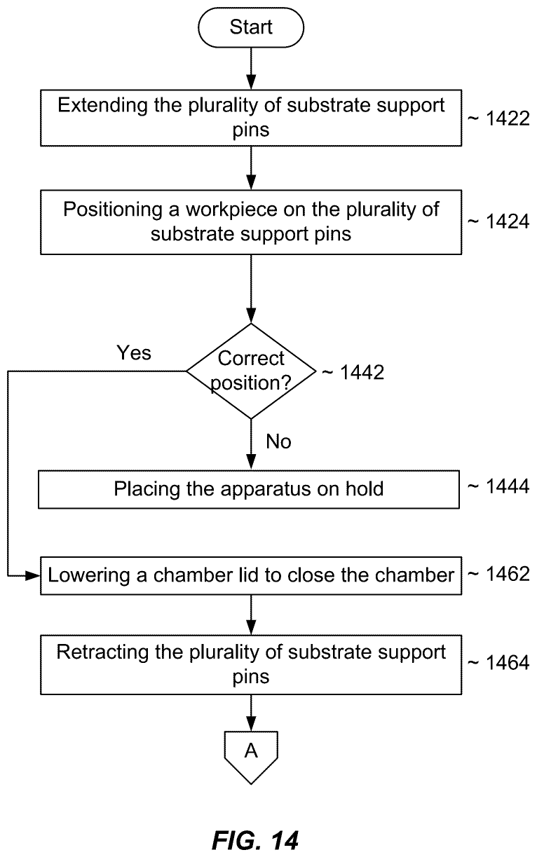

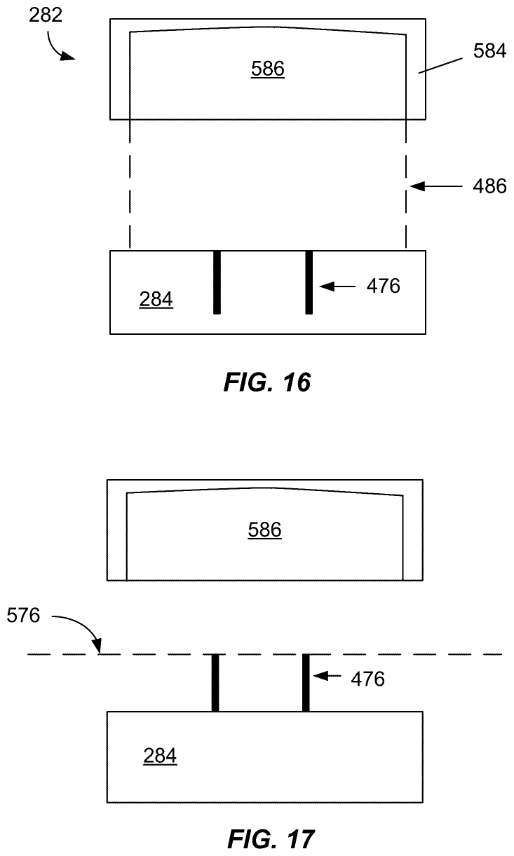

The method can include extending the plurality of substrate support pins at block 1422 in FIG. 14. FIG. 16 includes a cross-sectional view of a portion of the post-exposure bake unit 282. In the post-exposure bake unit 282, the plurality of substrate support pins 476 are in a retracted state within the substrate chuck 284. In FIG. 16 and subsequent figures, only two substrate support pins are illustrated to simplify understanding of the post-exposure bake unit 282 during processing. In practice, the plurality of substrate support pins 476 may include three or more substrate support pins.

The controller 250 or a local controller can transmit a signal that is received by the support pin actuator 478 for the plurality of substrate support pins 476 to be extended such that the plurality of substrate support pins 476 are in an extended state as illustrated in FIG. 17. Distal ends of at least three substrate support pins, two of which are illustrated in FIG. 17, can lie along the substrate support plane 576.

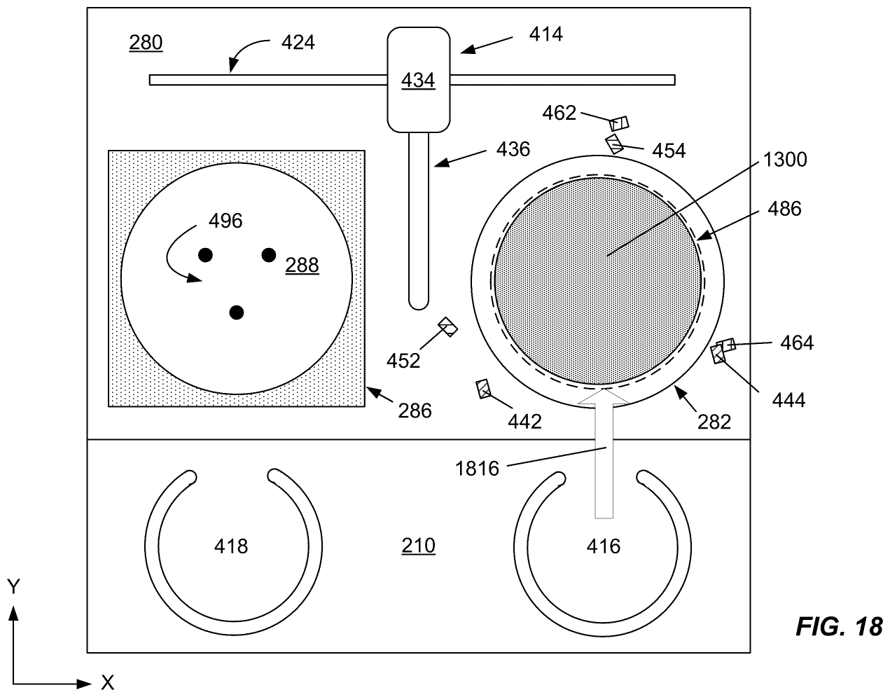

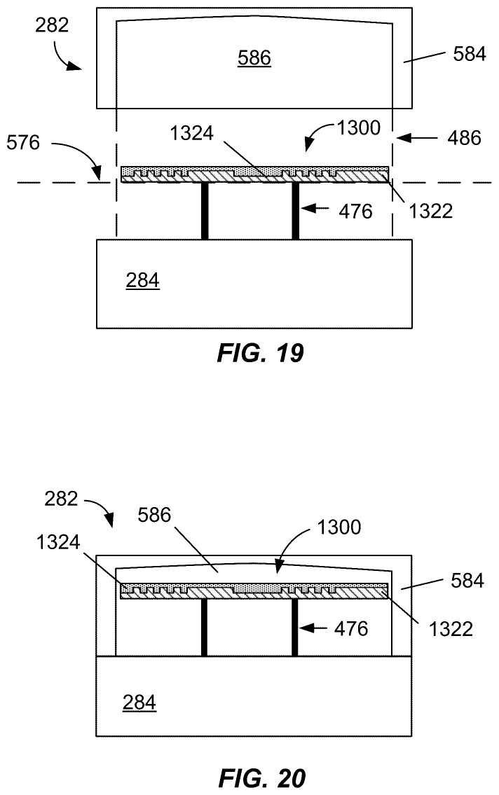

The method can include positioning a workpiece on the plurality of substrate support pins at block 1424 in FIG. 14. Referring to FIG. 18, the workpiece 1300 is moved into the post-exposure bake unit 282 using a substrate positioning tool that includes a robot hand 416 of the substrate transfer tool 210. The workpiece 1300 can move along a chamber ingress path 1816 into the post-exposure bake unit 282. The workpiece 1300 is positioned onto the plurality of substrate support pins 476 as illustrated in FIG. 19. The substrate 1322 is disposed between the cured planarization layer 1324 and the plurality of substrate support pins 476. The bottom surface of the workpiece 1300 lies substantially along the substrate support plane 576. The workpiece can be in the form of a wafer having a diameter of 200 mm, 300 mm, or 400 mm. The gap between the workpiece 1300 and the outer periphery of the processing zone 486 may be at most 5 mm, at most 2.5 mm, or at most 1 mm. If the workpiece 1300 is not properly positioned over the plurality of substrate support pins 476, the workpiece 1300 may be damaged when the chamber lid 584 is lowered.

The method can include determining whether or not the workpiece 1300 is in the correct position at decision diamond 1442 in FIG. 14. The controller 250 or a local controller can transmit a signal for the radiation emitters to activate. The determination can be made using a technique described with respect to FIGS. 6 and 7 except that the workpiece 622 is replaced by the workpiece 1300. In another implementation, the layout and design in FIGS. 8 and 9 or the design in FIGS. 10 and 11 may be used as an alternative to the design in FIGS. 6 and 7. For any of the designs, the sensor housing-component pair can have (1) a sensor housing that includes a sensor and a radiation emitter and a component that includes a radiation reflector or (2) a sensor housing that includes a sensor and may or may not include a radiation emitter and a component that includes a radiation emitter. The description below is based on the sensor design in FIGS. 6 and 7 and the sensor-radiation pair has a sensor including a radiation emitter and the component is a radiation reflector. After reading this specification, skilled artisans will be able to design and use the post-exposure bake apparatus 103 that has a different sensor design, a sensor housing-component pair where the component includes a radiation emitter, or both.

Referring to FIGS. 6, 7, and 19, the radiation emitters within the sensor housings 642, 652, and 662 emit radiation that is reflected by the components 644, 654, and 664, which are radiation reflectors in this implementation. The reflected radiation is at least partly occluded by the workpiece 1300, and such partly occluded radiation is received and sensed by the sensors of the sensor housings 642, 652, and 662 to generate signals that can be transmitted to the controller 250 or a local controller. The signals from the sensors of the sensor housings 642, 652, and 662 can be transmitted to and received by the controller 250 or a local controller. The controller 250 or the local controller may have access to data that correlates sensed radiation intensity to position within the chamber and can determine whether the workpiece 1300 is within or extends outside the processing zone 486.

If the position of the workpiece 1300 is such that the workpiece extends outside the processing zone 486, the workpiece is not in the correct position (“No” branch from decision diamond 1442), and the method can further include placing the apparatus on hold at block 1444 of FIG. 14. Many different actions may be performed. For example, the workpiece 1300 can be removed, the substrate transfer tool 210 may be recalibrated or receive other maintenance to ensure workpieces can be properly placed within the post-exposure bake unit 282. In another example, the workpiece 1300 may be removed and inspected, as the workpiece 1300 may have been previously damaged or have a shape that is different from workpieces used in generating empirical data that correlate radiation intensity to position within the chamber. Another action may be performed after the apparatus is placed on hold.

If the position of the workpiece 1300 is such that the workpiece does not extend outside the processing zone 486, the workpiece is in the correct position (“Yes” branch from decision diamond 1442), and the method can further include lowering a chamber lid to close the chamber at block 1462 after the arm is removed from the processing zone 486. The controller 250 or local controller can transmit a signal for the chamber lid 584 to be lowered to a closed position and close the chamber as illustrated in FIG. 20. The processing region 586 of the chamber that generally corresponds to the cavity in the chamber lid 584. In an alternative implementation, block 1422 is performed after decision diamond 1442, and block 1424 includes positioning the workpiece 1300 in the processing zone 486. After the workpiece 1300 is in its proper position, the plurality of substrate support pins 476 can be extended to support the workpiece 1300, and the robot hand 416 can be removed so that it does not extend into the processing zone 486.

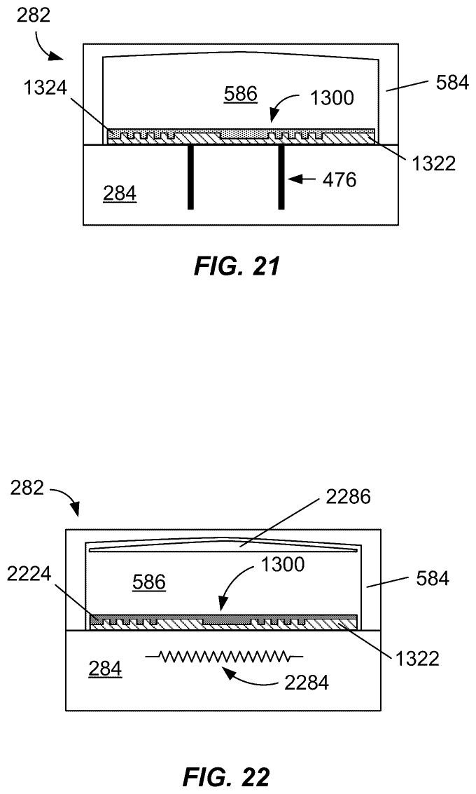

The method can include retracting the plurality of substrate support pins in block 1464 in FIG. 14. Referring to FIGS. 2 and 21, the controller 250 or a local controller can transmit a signal that is received by the support pin actuator 478 for the plurality of substrate support pins 476 to be moved from the extended state to the retracted state. The plurality of substrate support pins 476 may be retracted before, after, or while the chamber lid 584 is being lowered. The workpiece 1300 can be in contact with the substrate chuck 284 within the post-exposure bake unit 282. The workpiece 1300 can be resting on supports of the substrate chuck 284 or can be held in place by a vacuum, an electrostatic charge, or electromagnetism. The controller 250 or local controller can transmit a signal for a vacuum actuator or a circuit for the electrostatic charge or electromagnetism of the substrate chuck 284 to be activated, so that the workpiece 1300 is held in place during processing within the post-exposure bake unit 282.

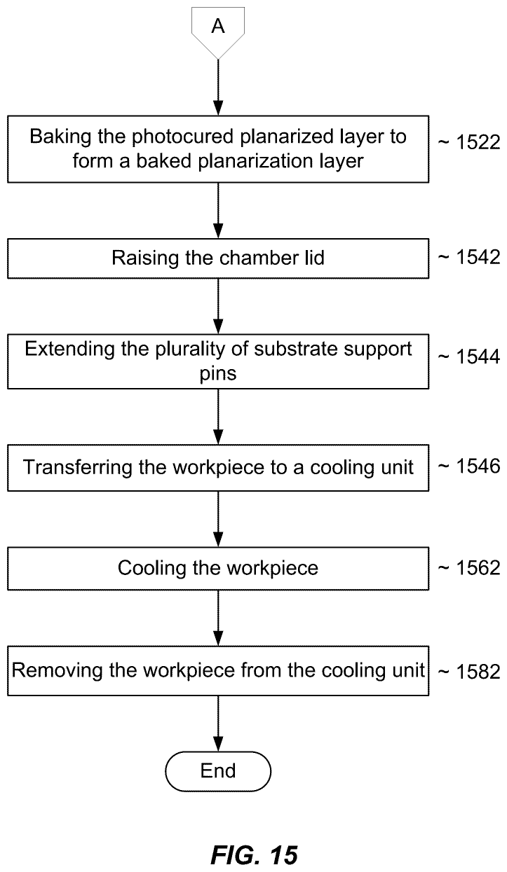

The method can further include baking the cured planarized layer to form a baked planarization layer at block 1522 in FIG. 15. During the baking operation, the material within the cured planarization layer 1324 can further polymerize, cross-link, or both. The baking operation can also help remove a relatively volatile component, if present, from the cured planarization layer 1324 in FIG. 21 when forming a baked planarization layer 2224 in FIG. 22.

A heating means within the post-exposure bake unit 282 can include a resistive heating element, a radiative heating element, or a gas flow system (for example, a heater and a fan) that provides a heated gas for convection heating. FIG. 22 illustrates a resistive heating element 2284 within the substrate chuck 284 and a radiative heating element 2286, for example, a heat lamp, positioned over the substrate chuck 284. The heating means as illustrated or described with respect to the post-exposure bake unit in FIG. 22 may be present in other figures that include the post-exposure bake unit 282 but are not illustrated to improve understanding of the post-exposure bake unit 282. Similarly, the plurality of substrate support pins 476 may be present in the post-exposure bake unit 282 but is not illustrated in FIG. 22 to improve understanding of the heating means for the post-exposure bake unit 282.

The heating means provides heat at a temperature higher than the temperature used for a radiation exposure operation in the cure apparatus 101. The baking temperature can be at least 300° C., at least 325° C., or at least 350° C. The baking temperature should not be so high as to cause significant decomposition or another adverse effect to the baked planarization layer 2224. The baking temperature can be at most 500° C., at most 450° C., or at most 400° C. The baking temperature can be a value between any of the minimum and maximum numbers noted above, for example, in a range from 300° C. to 500° C., 300° C. to 450° C., or 300° C. to 400° C. In a particular implementation, the baking temperature can be in a range from 350° C. to 400° C.

A soak time is the time the workpiece 1300 is at the baking temperature. The soak time needs to be sufficient to achieve a needed or desired amount of further polymerization or cross-linking, reduce the amount of a volatile component within the polymer layer to a desired amount, or both. The soak time can be at least 0.25 minute, at least 1 minute, or at least 3 minutes. After a long enough time, further exposure to the baking temperature may not sufficiently improve the polymer layer (a sufficient amount of polymerization or cross-linking has occurred, a remaining amount of the volatile component is low enough to not cause a problem during subsequent processing, etc.) or may start to cause an adverse effect, such as roughening the upper surface of the baked planarization layer 2224, possible delamination of the baked planarization layer 2224 from the workpiece 1300, or the like. The soak time may be at most 30 minutes, at most 20 minutes, at most 15 minutes, at most 2 minutes, or at most 1 minute. The soak time can be a value between any of the minimum and maximum numbers noted above, for example, in a range from 0.25 minute to 30 minutes, 1 minute to 20 minutes, or 2 minutes to 15 minutes.

The baking operation can be performed using a gas. The gas can include a material that is relatively inert to the cured planarization layer 1324 and the baked planarization layer 2224. The material can include N₂, CO₂, a noble gas (Ar, He, or the like), or a mixture thereof. The gas may not include an oxidizing material, for example O₂, O₃, N₂O, or the like, or may include no more than 2 mol % or no more than 0.5 mol % of the oxidizing material. The chamber lid 584 can be used to control a composition of gases above the workpiece 1300 during the baking operation. The inventors have found that keeping the gap between workpiece 1300 and the chamber lid 584 narrow improves the speed at which the composition of gases above the workpiece 1300 reaches a target composition.

As illustrated, the post-exposure bake units 282 are adapted to process a single workpiece at a time. In another implementation, the post-exposure bake units 282 can be adapted to process a plurality of workpieces during the same baking operation. The post-exposure bake units 282 may include a cassette or another suitable substrate container or be capable of receiving the cassette or the other suitable substrate container, where the cassette or the other suitable substrate container can hold a plurality of workpieces.

The memory 252, a database, or another memory outside the post-exposure bake apparatus 103 can include information regarding the composition of or polymer precursor used to form the cured planarization layer 1324, a desired baking temperature, a desired soak time to form the baked planarization layer 2224, or a combination thereof. Referring to FIG. 2, the controller 250 or a local controller can transmit a signal for the post-exposure bake unit 282 to flow the inert gas within the post-exposure bake unit 282 and control the heating means to maintain the workpiece 1300 at or within an allowable tolerance of the desired baking temperature for the soak time. The allowable tolerance may be +/−10° C., +/−5° C., or +/−2° C. of the desired baking temperature. Referring to FIG. 22, during heating, the controller 250 or a local controller can receive temperature data from a temperature sensor (not illustrated) within the substrate chuck 284 or a proximity temperature sensor (not illustrated). The temperature sensor within the substrate chuck 284 can be located where it can be in contact with or close proximity (for example, within 1 mm) of the workpiece 1300 when the substrate is located over substrate chuck 284. The proximity temperature sensor can receive near infrared radiation from the workpiece 1300 and be used to determine a temperature of the substrate 1322 or the cured planarization layer 1324.

The controller 250 or the local control can transmit a signal for the heating means, such as the resistive heating element 2284 or the radiative heat element 2286, to heat the workpiece 1300 and the cured planarization layer 1324 to the baking temperature or to maintain the temperature within the post-exposure bake unit 282 at the baking temperature. After the soak time, the controller 250 or a local controller can transmit a signal for the heating means to be deactivated.

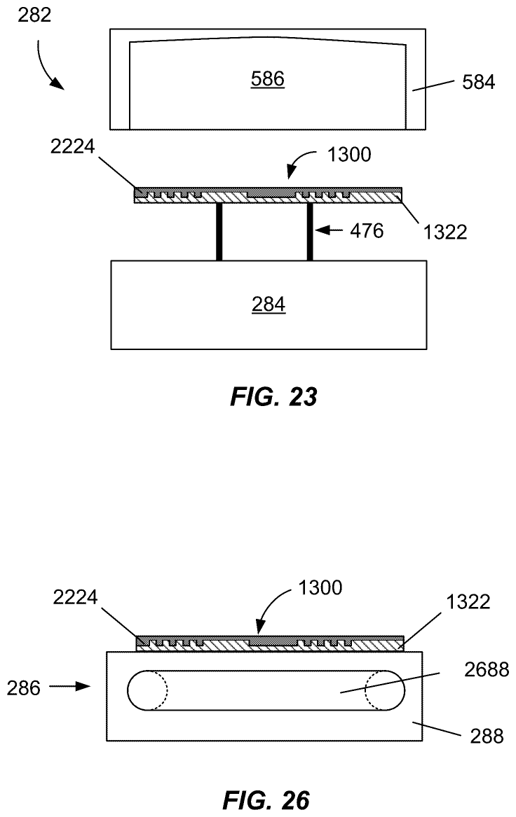

The method can include raising the chamber lid at block 1542 and extending the plurality of substrate support pins at block 1544 in FIG. 15. Referring to FIGS. 2 and 23, the controller 250 or a local controller can transmit a signal for the chamber lid 584 to be raised. Before the plurality of substrate support pins 476 are extended, the controller 250 or local controller can transmit a signal for the vacuum actuator or the circuit for the electrostatic charge or electromagnetism of the substrate chuck 284 to be deactivated, so that the workpiece 1300 can be lifted by the plurality of substrate support pins 476. If applicable, the controller 250 or local controller can actuate a backfill valve to allow a gas to flow into a vacuum channel, a vacuum zone, or both so that the workpiece 1300 is no longer at a vacuum pressure used to hold the workpiece 1300. The controller 250 or a local controller can transmit a signal that is received by the support pin actuator 478 for the plurality of substrate support pins 476 to be extended to the extended state. The chamber lid 584 may be raised before or after the plurality of substrate support pins 476 are extended.

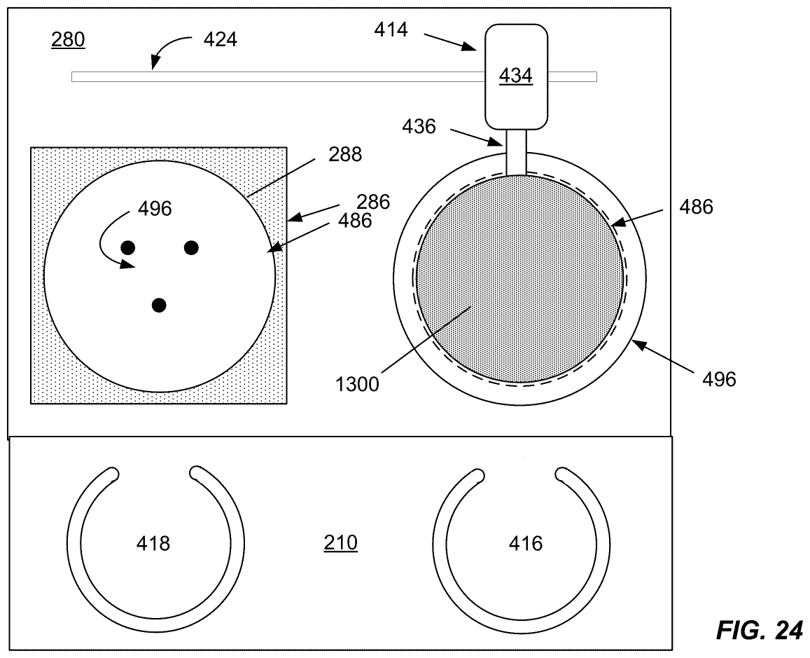

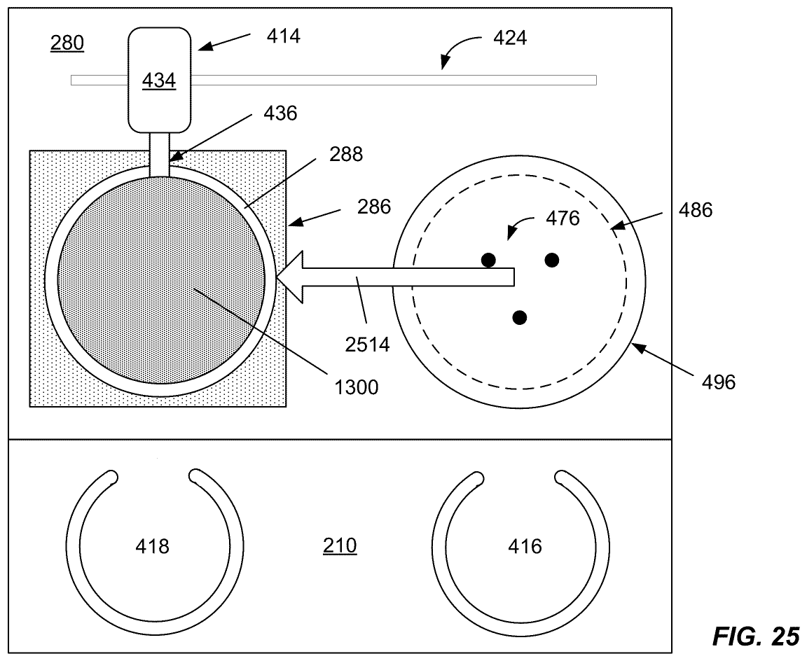

The method can further include transferring the workpiece to a cooling unit at block 1546 in FIG. 15. FIGS. 24 and 25 illustrate the transfer operation using the substrate positioning tool 414. Referring to FIG. 24, the controller 250 or a local controller can transmit a signal for the body 434 to be moved along the rail 424 so that the arm 436 is over the substrate chuck 284, an end effector of the arm 436 is under the workpiece 1300 and a signal for the arm 436 or a component (not illustrated) coupled to the arm 436 to hold the workpiece 1300. The end effector of the arm 436 may be around, above, or between the plurality of substrate support pins 476. The substrate support pins 476 may be lowered so that the workpiece 1300 rests on the end effector of the arm 436. Referring to FIG. 25, the controller 250 or a local controller can transmit a signal for the body 434 to be moved along the rail 424 so that the workpiece 1300 moves along a transfer path 2514 that can include a chamber egress path and a cooling unit ingress path. The workpiece 1300 is moved over the substrate chuck 288 of the cooling unit 286. The controller 250 or a local controller can transmit a signal for the arm 436 or a component (not illustrated) coupled to the arm 436 to release the workpiece 1300. Alternatively, the controller 250 may send instructions to at least one of the substrate support pins 496 and the arm 436, to raise the workpiece 1300 above the arm 436. The end effector of the arm 436 may then be withdrawn from between the plurality of substrate support pins 496. The workpiece 1300 can be in contact with the substrate chuck 288 within the cooling unit 286. The workpiece 1300 can be held in place by a vacuum, an electrostatic charge, or electromagnetism. The controller 250 or local controller can transmit a signal for a vacuum actuator or a circuit for the electrostatic charge or electromagnetism of the substrate chuck 288 to be activated.

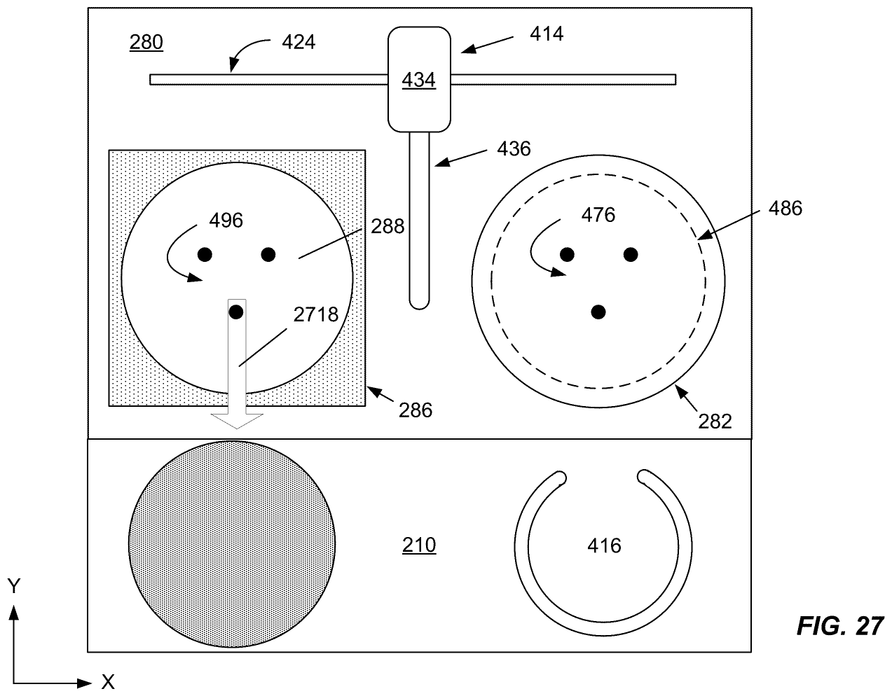

The method can include cooling the workpiece at block 1562 in FIG. 15. In an implementation, the cooling unit 286 can include a chill plate. Referring to FIG. 26, the substrate chuck 288 can include a flow channel 2688 through which a cooling fluid can flow. The substrate chuck 288 may or may not include a temperature sensor. The temperature of the workpiece 1300 may be sensed by the temperature sensor within the substrate chuck 288 or an optical temperature sensor. A cooling means associated with the cooling unit 286 may be activated before or after the workpiece 1300 is over the substrate chuck 288. The controller 250 or a local controller can transmit a signal to activate a pump to transfer the cooling fluid through the flow channel 2688, a valve to allow a compressed gas to expand within the cooling unit 286, a fan or pump to inject or recirculate a cooling gas within the cooling unit 286. Cooling of the workpiece 1300 may be performed until the temperature of the workpiece 1300 is sensed to be at most a temperature setpoint, for a predetermined time, or the earlier of reaching the temperature setpoint or expiration of the predetermined time. The temperature setpoint is sufficiently low enough to prevent or have a reduced likelihood of damaging the workpiece 1300 or substrate handling equipment, such as the robot hand 418 or another portion of a substrate positioning tool that is coupled to the robot hand 418, a substrate pod, or other equipment that may subsequently contact the workpiece 1300. In a particular implementation, the temperature setpoint can be at most 50° C.

The cooling means may remain in the activated state between processing workpieces or may be deactivated between processing workpieces. If the cooling means is deactivated between processing workpieces, the controller 250 or a local controller can transmit a signal to deactivate the pump that pumps the cooling fluid through the flow channel 2688, the valve that allows the compressed gas to expand within the cooling unit 286, or the fan or pump that injects or recirculates the cooling gas within the cooling unit 286.

The method can further include removing the workpiece from the cooling unit at block 1582 in FIG. 15. The controller 250 or local controller can transmit a signal for the vacuum actuator or the circuit for the electrostatic charge or electromagnetism of the substrate chuck 288 to be deactivated, so that the workpiece 1300 can be lifted by the plurality of substrate support pins 496. If applicable, the controller 250 or local controller can actuate a backfill valve to allow a gas to flow into a vacuum channel, a vacuum zone, or both so that the workpiece 1300 is no longer at a vacuum pressure used to hold the workpiece 1300 in place. Referring to FIGS. 25 and 27, the controller 250 or a local controller can transmit a signal for the plurality of substrate support pins 496 to be extended to the extended state.

The workpiece 1300 can be removed from the cooling unit 286 using a robot hand 418 of the substrate positioning tool along a cooling unit egress path 2718. The controller 250 or a local controller can transmit a signal for the robot hand 418 to be extended into the cooling unit 286 and remove the workpiece 1300 from the plurality of substrate support pins 496. After the workpiece is removed from the cooling unit 286, the controller 250 or a local controller can transmit a signal for the plurality of substrate support pins 496 to be retracted to a retracted state within the substrate chuck 288 so that workpiece 1300 rests on the robot hand 418. The workpiece 1300 can subsequently be moved to the substrate pod 271, 291, another substrate pod, and another suitable location within the post-exposure bake section 270 or elsewhere within the system 100.

A method of manufacturing an electronic device can include any of the methods previously described. The workpiece 1300 can be further processed to form substantially completed electronic devices, wherein any one or more of the electronic devices can include an electrical circuit element, an optical element, a microelectromechanical system (MEMS), a recording element, a sensor, a mold, an integrated circuit, a power transistor, a charge coupled-device (CCD), an image sensor, a microfluidic device, or the like. The integrated circuit may be a solid state memory (such as a dynamic random access memory (DRAM), a static random access memory (SRAM), a flash memory, and a magnetoresistive memory (MRAM)), a microprocessor, a microcontroller, a graphics processing unit, a digital signal processor, a field programmable gate array (FPGA) or a semiconductor element, or the like.

Implementations of the system, apparatuses and methods can be useful to ensure the proper placement of a workpiece within a processing chamber or other equipment. The method is well suited for a processing chamber that has a harsh environment when processing the workpiece. The harsh environment may include a high temperature, a toxic, corrosive, flammable, pyrophoric, or other dangerous gas. By ensuring the proper placement of the workpiece while within the processing chamber, the workpiece is less likely to be damaged or misprocessed within the processing chamber due to improper placement of the workpiece within the processing chamber or other equipment.

Sensor housing-component pairs can be strategically placed to avoid contacting the workpiece, the chamber lid, equipment used to move the workpiece in and out of the processing chamber, any other equipment, or a combination thereof during the movement or processing of the workpiece. The method allows a user to select a sensor housing-component pair selected from the group consisting of (1) a sensor housing that includes a sensor and a radiation emitter and a component that includes a radiation reflector that reflects radiation emitted by the radiation emitter and (2) a sensor housing that includes a sensor and may or may not include a radiation emitter and a component that includes a radiation emitter. Any one or more of the sensor housing-component pairs can be positioned so that the radiation beam from the radiation emitter is partly occluded by the workpiece or passes along a location closest to the workpiece where such location is between the workpiece and the outer periphery of a processing zone. When the radiation beam is partly occluded, as few as two sensor housing-component pairs can be used. When the radiation beam passes between the workpiece and the outer periphery of the processing zone, as few as three sensor housing-component pairs may be used. If needed or desired more sensor housing-component pairs may be used for a particular application.

Note that not all of the activities described above in the general description or the examples are required, that a portion of a specific activity may not be required, and that at least one further activity can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of systems and apparatuses that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. An apparatus, comprising:
a chamber including a processing zone, wherein the chamber is adapted to support a workpiece along a substrate support plane;
a first sensor adapted to:
receive a first radiation beam adapted to pass through the processing zone; and
generate a first signal in response to receiving the first radiation beam,
wherein:
the first radiation beam propagates along a first line that is at a first acute angle relative to the substrate support plane, and
the first sensor is outside the processing zone; and
a controller adapted to receive the first signal and determine first information regarding a position of the workpiece within the chamber in response to receiving the first signal.

2. The apparatus of claim 1, wherein the first acute angle is in a range from 0° to 9.9°.

3. The apparatus of claim 1, wherein the workpiece includes a substrate and a cured planarization layer.

4. The apparatus of claim 1, wherein the chamber further comprises a plurality of substrate support pins having distal ends, wherein the distal ends of at least three substrate support pins within the plurality of substrate support pins lie along the substrate support plane.

5. The apparatus of claim 1, wherein the chamber further includes a lid adapted to be moved to a closed position after all of the workpiece is determined to be within the processing zone, and, from a top view, the lid does not overlap or underlap the first sensor.

6. The apparatus of claim 1, further comprising a second sensor, wherein:
the second sensor is adapted to:
receive a second radiation beam adapted to pass through the processing zone; and
generate a second signal in response to receiving the second radiation beam,
wherein:
the second radiation beam propagates along a second line that is at a second acute angle relative to the substrate support plane, and
the second sensor is outside the processing zone, and
the controller is adapted to receive the second signal and determine second information regarding the position of the workpiece in response to receiving the second signal.

7. The apparatus of claim 6, wherein the chamber further comprises a plurality of substrate support pins adapted to move the workpiece in at least an X-direction or a Y-direction that is parallel to the substrate support plane.

8. The apparatus of claim 6, wherein:
$$0. ° \leq \vert ( α - β ) \vert \leq 0.1 ° , \qquad Equation 1$$
where α is the first acute angle, and B is the second acute angle.

9. The apparatus of claim 6, wherein:
$$0.1 ° < \vert ( α - β ) \vert \leq 9.9 ° , \qquad Equation 2$$
where α is the first acute angle, and B is the second acute angle.

10. The apparatus of claim 6, further comprising a third sensor, wherein:
the third sensor is adapted to:
receive a third radiation beam adapted to pass through the processing zone and along the substrate support plane; and
generate a third signal in response to receiving the third radiation beam,
wherein:
the third radiation beam propagates along a third line that is at a third acute angle relative to the support plane, and
the third sensor is outside the processing zone, and
the controller is adapted to receive the third signal and determine third information regarding the position of the workpiece in response to receiving the third signal.

11. The apparatus of claim 10, wherein the first radiation beam, the second radiation beam, and the third radiation beam do not interfere with one another.

12. The apparatus of claim 1, wherein the processing zone includes a high-temperature zone adapted to heat the workpiece.

13. The apparatus of claim 1, wherein the processing zone includes a bake zone adapted to heat the workpiece overlying the workpiece in an ambient having at most 2 mol % O₂.

14. The apparatus of claim 13, wherein the apparatus comprises a post-exposure bake unit adapted to bake a cured planarization layer and a cooling unit adapted to cool the workpiece, wherein the post-exposure bake unit is separate from the cooling unit.

15. The apparatus of claim 1, wherein the processing zone:
includes a deposition zone adapted to deposit a first material over the workpiece;
includes an etch zone adapted to etch a second material within the workpiece; or
is adapted to deposit a third material over the workpiece during a first point in time and etch a portion of the third material during a second point in time.

16. The apparatus of claim 1, further comprising:
a component radiatively coupled to the first sensor, wherein:
the component includes a radiation reflector or a radiation emitter, and the apparatus is adapted such that:
(1) the first sensor is at a first elevation above an elevation of the substrate support plane, and the component is at a second elevation below the elevation of the substrate support plane, or
(2) the first sensor is at a third elevation below the elevation of the substrate support plane, and the component at a fourth elevation above the substrate support plane.

17. An apparatus, comprising:
a chamber including a processing zone, wherein the chamber is adapted to support a workpiece along a substrate support plane;
a first substrate positioning tool adapted to move the workpiece along a chamber ingress path into the processing zone, wherein the chamber ingress path is along a first line;
a second substrate positioning tool adapted to move the workpiece along a chamber egress path out of the processing zone, wherein the chamber egress path is along a second line, and, from a top view, the second line intersects the first line;
a first sensor adapted to:
receive a first radiation beam that passes through the processing zone and along the substrate support plane; and
generate a first signal in response to receiving the first radiation beam,
wherein the first sensor is located outside the processing zone and where the first sensor does not contact the workpiece, the first substrate positioning tool, and the second substrate positioning tool at any time when the workpiece is moved along each of the chamber ingress path and the chamber egress path.

18. The apparatus of claim 17, wherein:
the chamber further comprises a plurality of substrate support pins having distal ends,
the apparatus further comprises a support pin actuator adapted to reversibly move the plurality of substrate support pins between a retracted state and an extended state, and
when in the extended state, the distal ends of at three support pins within the plurality of substrate support pins lie along the substrate support plane.

19. The apparatus of claim 17, further comprising a cooling unit, and a third substrate positioning tool wherein:
the processing zone is a high-temperature zone,
the first substrate positioning tool is adapted to load the workpiece into the high-temperature zone along the chamber ingress path,
the second substrate positioning tool is adapted to remove the workpiece from the high-temperature zone along the chamber egress path and load the workpiece into the cooling unit along a cooling unit ingress path, and
the third substrate positioning tool is adapted to remove the workpiece from the cooling unit along a cooling unit egress path.

20. A method of making an electronic device, comprising:
loading a workpiece onto support pins having distal ends, wherein the distal ends of at least three support pins lie along a substrate support plane, wherein the support pins are within a processing zone of a chamber;
receiving a first radiation beam at a first sensor, wherein:
the first radiation beam propagates along a line that is at a first acute angle relative to the substrate support plane, and
the first sensor is outside the processing zone;
generating a first signal in response to receiving the first radiation beam, wherein generating is performed by the first sensor;
receiving the first signal at a controller; and
determining a first information regarding a position of the workpiece in response to receiving the first signal, wherein determining is performed by the controller.

21. The method of claim 20, wherein, during loading the workpiece onto the support pins, the workpiece includes a substrate and a cured planarization layer, wherein the substrate is disposed between the support pins and the cured planarization layer.

22. The method of claim 21, further comprising baking the cured planarization layer within the processing zone to form a baked planarization layer, wherein baking the cured planarization layer is performed after determining the first information.
